(19) United States
(12) Patent Application Publication
(10) Pub. No.: US 2025/0194367 A1
(43) Pub. Date: Jun. 12, 2025

(54) LIGHT EMITTING DEVICE INCLUDING A PLURALITY OF ORGANIC EL ELEMENTS

(71) Applicant: CANON KABUSHIKI KAISHA, Tokyo (JP)

(72) Inventor: HIDEKI HAYASHI, Kanagawa (JP)

(21) Appl. No.: 18/962,284

(22) Filed: Nov. 27, 2024

(30) Foreign Application Priority Data
Dec. 7, 2023 (JP) 2023-207168

(51) Int. Cl. H10K 59/131; G06F 1/16; H10K 102/00

(52) U.S. Cl. CPC H10K 59/1315; G06F 1/1652; H10K 2102/351

(57) ABSTRACT

A light emitting device having a plurality of organic EL elements arranged on a substrate includes an insulating film configured to insulate adjacent lower electrodes from each other among lower electrodes of the plurality of organic EL elements. The insulating film has a trench between the adjacent lower electrodes. A surface of the trench includes two opposing wall surfaces and a bottom surface located between the two wall surfaces. The bottom surface includes a convex surface protruding in a direction away from the substrate. In an opposing direction of the two wall surfaces, a width of the convex surface is not less than ⅓ of a shortest distance between the two wall surfaces.

### BACKGROUND OF THE INVENTION

### Field of the Invention

The present invention relates to a light emitting device including a plurality of organic EL elements, and an apparatus including the light emitting device.

### Description of the Related Art

In recent years, the pixel density in a display apparatus using organic Electro Luminescence (EL) elements is increasing. Along with this, a leakage current is readily generated between pixels through an organic layer commonly provided with respect to multiple pixels. If the leakage current is generated, for example, a non-light emitting pixel is influenced by a light emitting pixel and slightly emits light. This causes color mixing and a decrease in light emission efficiency.

Japanese Patent Laid-Open No. 2012-216338 proposes that, in order to reduce the leakage current between pixels, a trench is formed in an insulating layer, which separates the anode electrodes of organic EL elements from each other, to decrease the film thickness of the low resistance organic layer in the trench.

Even if the trench is formed in the insulating layer between the pixels, when the bottom surface of the trench is flat, the resistance value of the organic layer between the pixels is not sufficiently decreased, and a leakage current can be generated.

### SUMMARY OF THE INVENTION

The present invention provides a technique advantageous in reducing a leakage current.

One of aspects of the present invention provides a light emitting device including a plurality of organic EL elements arranged on a substrate, comprising an insulating film configured to insulate adjacent lower electrodes from each other among lower electrodes of the plurality of organic EL elements, wherein the insulating film has a trench between the adjacent lower electrodes, and a surface of the trench includes two opposing wall surfaces and a bottom surface located between the two wall surfaces, the bottom surface includes a convex surface protruding in a direction away from the substrate, and in an opposing direction of the two wall surfaces, a width of the convex surface is not less than ⅓ of a shortest distance between the two wall surfaces.

Further features of the present invention will become apparent from the following description of exemplary embodiments with reference to the attached drawings.

### BRIEF DESCRIPTION OF THE DRAWINGS

FIGS. 1A to 1C are sectional views each schematically showing the arrangement of a light emitting device according to an embodiment;

FIG. 2 is a schematic sectional view for explaining a manufacturing method of the light emitting device according to the embodiment;

FIG. 3 is a schematic sectional view for explaining the manufacturing method of the light emitting device according to the embodiment;

FIG. 4 is a schematic sectional view for explaining the manufacturing method of the light emitting device according to the embodiment;

FIG. 5 is a schematic sectional view for explaining the manufacturing method of the light emitting device according to the embodiment;

FIG. 6 is a schematic sectional view for explaining the manufacturing method of the light emitting device according to the embodiment;

FIG. 7 is a schematic sectional view for explaining the manufacturing method of the light emitting device according to the embodiment;

FIG. 8 is a schematic sectional view for explaining the manufacturing method of the light emitting device according to the embodiment;

FIG. 9 is a schematic sectional view for explaining the manufacturing method of the light emitting device according to the embodiment;

FIG. 10 is a view showing an application example of the light emitting device according to the embodiment;

FIGS. 11A and 11B are views each showing an application example of the light emitting device according to the embodiment;

FIGS. 12A and 12B are views each showing an application example of the light emitting device according to the embodiment;

FIGS. 13A and 13B are views each showing an application example of the light emitting device according to the embodiment;

FIGS. 14A and 14B are views each showing an application example of the light emitting device according to the embodiment; and

FIGS. 15A to 15C are views showing an application example of the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

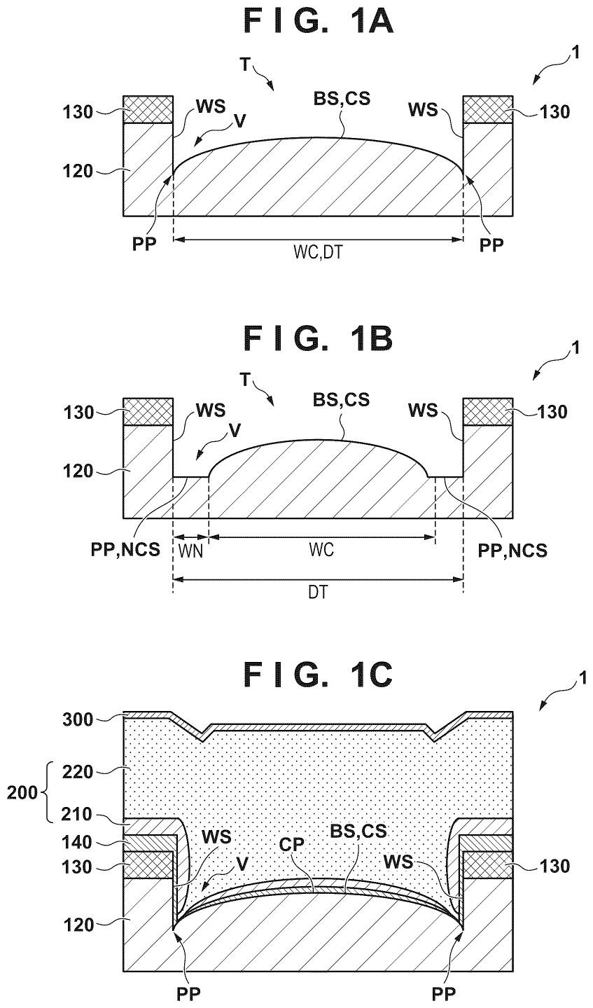

FIG. 1A is a schematic sectional view showing one aspect of a light emitting device 1 according to an embodiment. FIG. 1B is a schematic sectional view showing another aspect of the light emitting device 1 according to the embodiment. The light emitting device 1 includes a plurality of organic EL elements (not shown) arranged on a substrate (not shown). The light emitting device 1 includes an insulating film 120 that insulates adjacent lower electrodes 130 from each other among the lower electrodes 130 of the plurality of organic EL elements. The insulating film 120 has a trench T between the adjacent lower electrodes 130. The surface of the trench T can include two opposing wall surfaces WS and a bottom surface BS located between the two wall surfaces WS. The bottom surface BS can include a convex surface CS protruding in a direction away from the substrate (not shown). The convex surface CS is a region having the radius of curvature of a finite length and the center of curvature located below the bottom surface BS (on a substrate SUB side). The bottom surface BS may include a non-convex surface NCS between the two wall surfaces WS and the convex surface CS. As schematically shown in FIGS. 1A and 1B, in the opposing direction of the two wall surfaces WS, a width WC of the convex surface CS is preferably equal to or larger than ⅓ of a shortest distance DT between the two wall surfaces WS. In FIG. 1A, WC=DT. Alternatively, in the opposing direction of the two wall surfaces WS, a width WN of the non-convex surface NCS is preferably smaller than the width WC of the convex surface CS. FIG. 1A shows an example in which WN=0. The non-convex surface NCS can be, for example, a flat surface. The example schematically shown in FIG. 1A can be understood as an example in which the non-convex surface NCS is minimized or an example in which the non-convex surface NCS is removed. It may be understood that the bottom surface BS has the convex surface CS in a region including its central portion, and has a peripheral portion PP outside the central portion.

As will be described later in detail, the insulating film 120 can be an optical adjustment film. The optical adjustment film can have a thickness corresponding to the color (wavelength range) of light generated by the pixel. The insulating film 120 is formed by, for example, a plasma CVD method, and is, for example, a silicon oxide film. The lower electrode 130 is formed by, for example, a sputtering method, and is, for example, a transparent electrode formed of indium tin oxide (ITO film), indium zinc oxide (IZO film), or the like.

The trench T can be formed by sequentially forming an insulating material film for forming the insulating film 120 and a conductive material film for forming the lower electrode 130, and then processing the conductive material film and the insulating material film by a photolithography step and a dry etching step. The dry etching step can be executed under a condition with a small amount of etchant. With this, the etching rate increases at a position closer to the resist mask since the less etchant is consumed, and the etching rate decreases at a position farther from the resist mask since the more etchant is consumed. As a result, the peripheral portion in the trench T is etched more than the central portion in the trench T, so that the trench T having a structure as schematically shown in FIG. 1A or 1B can be obtained. The condition with a small amount of etchant is achieved by decreasing the pressure of a chamber where dry etching is performed, or reducing the flow rate of the etching gas.

The trench T whose bottom surface BS has the convex surface CS can also be understood as a structure where a narrow valley V exists in the peripheral portion PP or the non-convex surface NCS in the bottom surface BS. The valley V can be formed along each of the two wall surfaces WS. The valley V can be regarded as a narrow concave pattern. The valley V is advantageous in forming a structure in which, among a plurality of organic layers formed on the trench T, at least one organic layer, particularly a light emitting layer, and a hole injection layer, a hole transport layer, and the like that can be arranged between the light emitting layer and the insulating film 120 are interrupted or decreased in thickness in the valley V. This can increase the electric resistance of the organic film between adjacent pixels (organic EL elements), thereby reducing a leakage current between the adjacent pixels. On the other hand, among the plurality of organic layers, organic layers close to the upper electrode, for example, an electron transport layer, an electron injection layer, a charge generation layer, and the like that can be arranged on the light emitting layer are improved in continuity with no or reduced interruption as compared to the organic layer arranged between the light emitting layer and the insulating film 120. The continuity of the upper electrode also improves with no interruption.

It is not easy to form the narrow concave pattern as described above by the normal photolithography step and dry etching step. In an organic EL display apparatus, a step structure such as a bank structure can be formed between organic EL elements without using CMP. In a case of this step structure, for example, an organic layer is stacked on the step structure and its surface is planarized. Then, an insulating film is formed on the organic layer, and a resist pattern can be formed on the insulating film by a photolithography step. By performing etching using the resist pattern as an etching mask, a narrow concave pattern may be obtained. However, since this process requires many steps, production stability is concerned.

FIG. 1C is a sectional view schematically showing the structure of the light emitting device 1 that includes an insulating layer 140, an organic film (organic functional film) 200, and an upper electrode 300 stacked on the structure schematically shown in FIG. 1A. The insulating layer 140 is formed by, for example, a plasma CVD method, and is, for example, a silicon oxide film. The organic film 200 includes at least a light emitting layer, and may also include, for example, a charge injection layer (hole injection layer or electron injection layer), a charge transport layer (hole transport layer or electron transport layer), a charge blocking layer, and the like. The upper electrode 300 is desirably a thin-film transparent material so that the light generated in the organic film 200 is emitted to the upper surface without being blocked. The upper electrode 300 is formed by a thin film of, for example, gold, platinum, silver, aluminum, chromium, magnesium, or an alloy thereof.

In one aspect, the organic film 200 can include a low resistance layer 210 and a light emitting layer 220. Each of the low resistance layer 210 and the light emitting layer 220 is formed of an organic material. The resistance value of the low resistance layer 210 is lower than the resistance value of the light emitting layer 220. The low resistance layer 210 can include at least one of a hole injection layer, a hole transport layer, and a charge generation layer. The light emitting layer 220 generates light when a current flows through the light emitting layer 220. In the example shown in FIG. 1C, the organic film 200 includes one low resistance layer 210 and one light emitting layer 220. Instead, the organic film 200 may include light emitting layers corresponding to a plurality of light emission colors, and may be configured to emit white light.

The organic film 200 can be formed to fill the valley V. When the low resistance layer 210 is formed by vapor deposition, the low resistance layer 210 may decrease in thickness or be interrupted at or near the valley V. In the example shown in FIG. 1C, the low resistance layer 210 is interrupted at the valley V. If the low resistance layer 210 decreases in thickness as described above, the resistance value increases in this portion. As a result, the current flowing from the individual lower electrode 130 to the low resistance layer 210 is restricted at the valley V. This can reduce the leakage current between the adjacent organic EL elements.

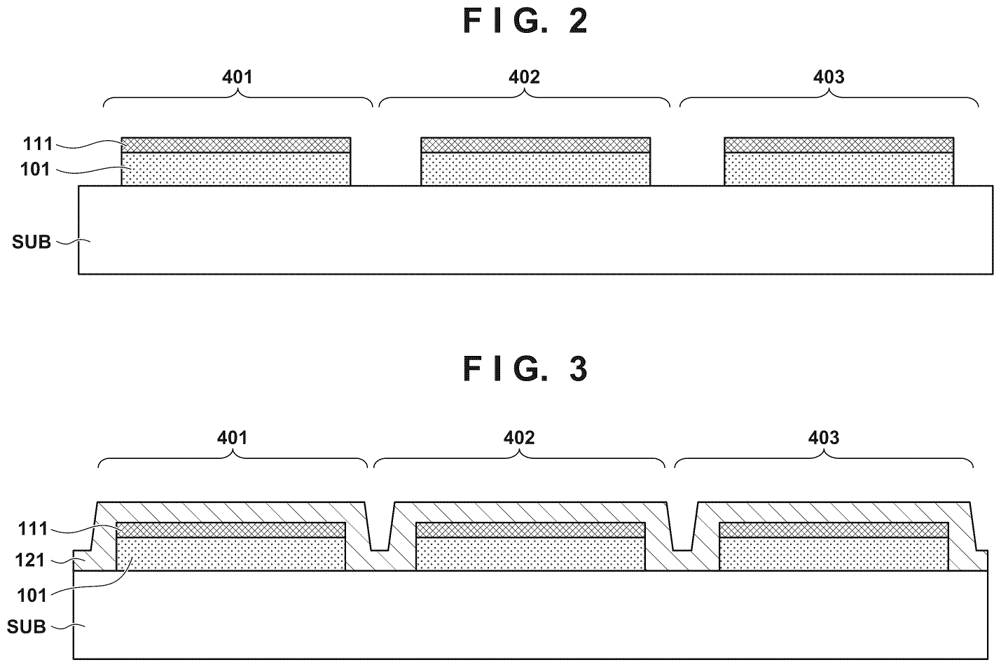

The manufacturing method of the light emitting device 1 will be described below with reference to FIGS. 2 to 9. FIGS. 2 to 9 show a region where three kinds of pixels (organic EL elements) 401, 402, and 403 that generate light beams of different wavelength ranges are formed. The manufacturing method of the light emitting device 1 exemplarily described below include steps A to H.

FIG. 2 schematically shows a state after performing step A. In step A, after forming a material layer for forming a reflective layer 101 and a material layer for forming a barrier layer 111 on the substrate SUB such as a semiconductor substrate, these material layers are patterned to form the reflective layer 101 and the barrier layer 111 for each of the pixels 401, 402, and 403. The patterning can include a photolithography step and a dry etching step. Although not shown in FIG. 2, transistors, wirings, and the like are formed in the substrate SUB. The reflective layer 101 can be, for example, an AlCu film formed by a sputtering method. The barrier layer 111 can be, for example, a Ti/TiN film formed by a sputtering method. The reflective layer 101 may be used as a part of a wiring pattern by electrically connecting a wiring layer (not shown) formed in the substrate SUB and the reflective layer 101 via a conductive plug or the like. The reflective layer 101 reflects the light generated in an organic film (light emitting layer) (to be formed later) so that the light is extracted upward. The barrier layer 111 can function as a barrier metal for the reflective layer 101. The barrier layer 111 can also function as an intermediate layer for electrically connecting the reflective layer 101 to the lower electrode (to be formed later), that is, a layer for reducing conduction failure between the reflective layer 101 and the lower electrode. The barrier layer 111 can also function to provide good image quality by providing a barrier layer with low reflectivity between pixels so that reflection between the pixels is suppressed and resonance/amplification is performed only in the pixel portion.

FIG. 3 schematically shows a state after performing step B. In step B, an insulating layer 121 is formed. The insulating layer 121 is formed by, for example, a plasma CVD method, and can be, for example, a silicon oxide film. Step B can be omitted. However, executing step B is advantageous in causing the pixels 401, 402, and 403 to have a common film configuration upon sequentially dry-etching the insulating layer, the barrier layer, and the reflective layer to form a reflective surface in a later step, thereby stabilizing the manufacturing process.

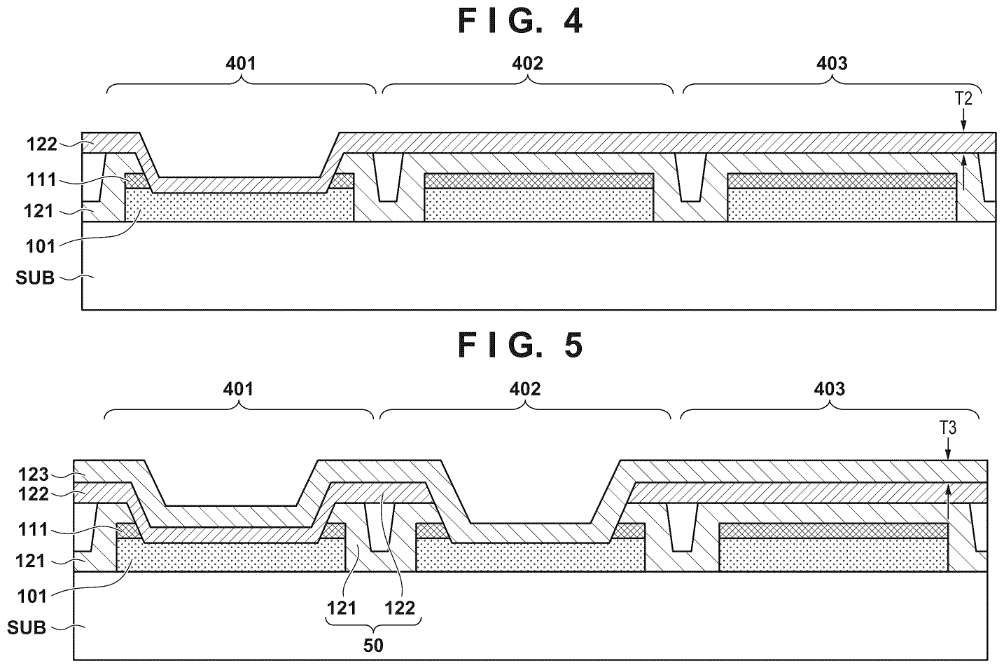

FIG. 4 schematically shows a state after performing step C. In step C, after forming an opening portion for a reflective surface by performing a photolithography step and a dry etching step on the film configuration for the pixel 401, an insulating layer 122 is formed. In a step of forming the opening portion in step C, the insulating layer 121, the barrier layer 111, and the reflective layer 101 are sequentially etched. The wall surface of the opening portion to be formed may be perpendicular to the upper surface of the substrate SUB, or may be tapered. The insulating layer 122 is formed by, for example, a plasma CVD method, and is, for example, a silicon oxide film. Let T2 be the thickness of the insulating layer 122. T2 can be, for example, about 60 nm.

FIG. 5 schematically shows a state after performing step D. In step D, after forming an opening portion for a reflective surface by performing a photolithography step and a dry etching step on the film configuration for the pixel 402, an insulating layer 123 is formed. In a step of forming the opening portion in step D, the insulating layer 122, the insulating layer 121, the barrier layer 111, and the reflective layer 101 are sequentially etched. The wall surface of the opening portion to be formed may be perpendicular to the upper surface of the substrate SUB, or may be tapered. The insulating layer 123 is formed by, for example, a plasma CVD method, and is, for example, a silicon oxide film. Let T3 be the thickness of the insulating layer 123. T3 can be, for example, about 60 nm.

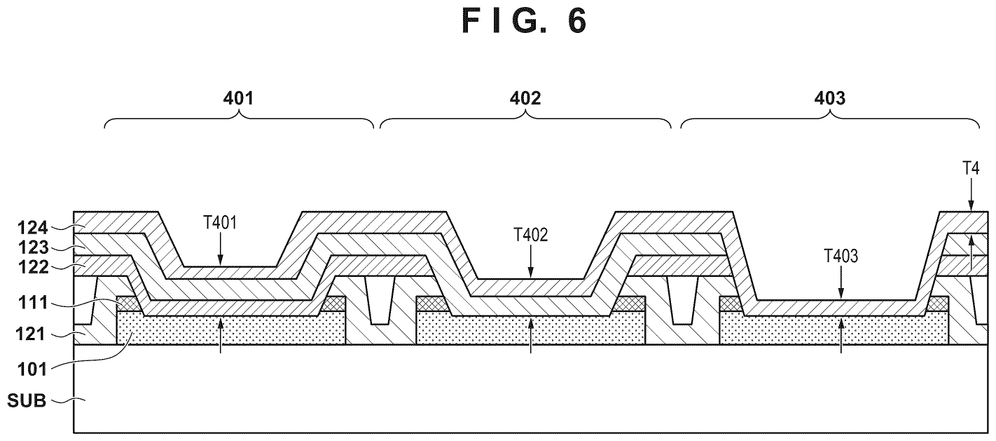

FIG. 6 schematically shows a state after performing step E. In step E, after forming an opening portion for a reflective surface by performing a photolithography step and a dry etching step on the film configuration for the pixel 403, an insulating layer 124 is formed. In a step of forming the opening portion in step E, the insulating layer 123, the insulating layer 122, the insulating layer 121, the barrier layer 111, and the reflective layer 101 are sequentially etched. The wall surface of the opening portion to be formed may be perpendicular to the upper surface of the substrate SUB, or may be tapered. The insulating layer 124 is formed by, for example, a plasma CVD method, and is, for example, a silicon oxide film. Let T4 be the thickness of the insulating layer 124. T4 can be, for example, about 110 nm.

A thickness T401 (first thickness) of the optical adjustment layer of the pixel 401 corresponds to T2+T3+T4, a thickness T402 (second thickness) of the optical adjustment layer of the pixel 402 corresponds to T3+T4, and a thickness T403 (third thickness) of the optical adjustment layer of the pixel 403 corresponds to T4. In this manner, three kinds of optical adjustment layers having different thicknesses can be formed. Here, T401>T402>T403. Two kinds or four or more kinds of optical adjustment layers can be formed by a similar method.

In the above-described method, the thicknesses of the optical adjustment layers need not be controlled by etching or the like but can be controlled by the thickness upon forming each insulating layer. Accordingly, the optical adjustment layer having a thickness suitable for optical resonance of each pixel can be stably obtained.

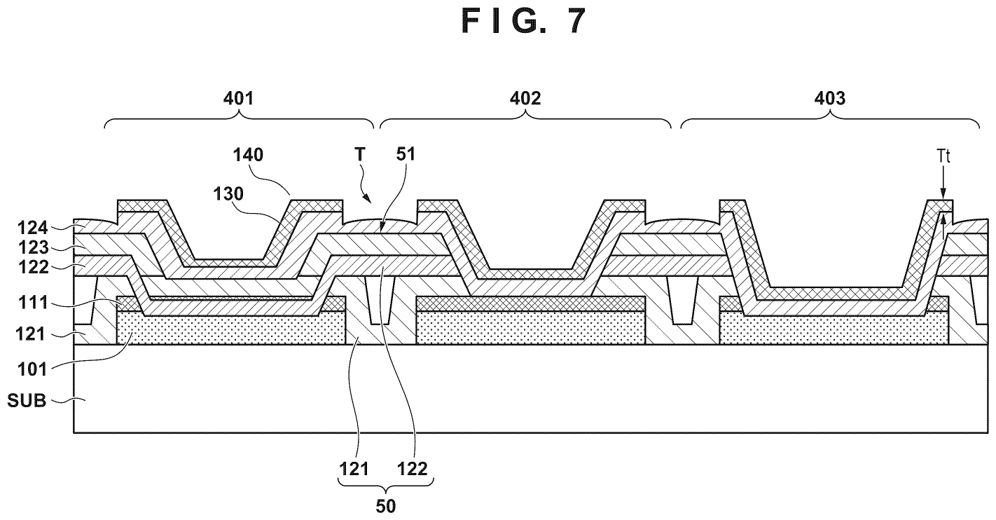

FIG. 7 schematically shows a state after performing step F. In step F, after forming a material layer for the lower electrode 130, the material layer is patterned to form the lower electrode 130 for each of the pixels 401, 402, and 403. This patterning can include a photolithography step and a dry etching step. The lower electrode 130 is formed of, for example, indium tin oxide (ITO) or indium zinc oxide (IZO). The material layer for the lower electrode 131 is formed by, for example, a sputtering method. Let Tt be the thickness of the lower electrode 130.

By using a condition with a small amount of etchant as the dry etching condition for forming the lower electrode 130, the characteristic structure as schematically shown in FIG. 1A or 1B can be obtained. This is because the etching rate increases at a position closer to the resist mask formed by the photolithography step since the less etchant is consumed, and the etching rate decreases at a position farther from the resist mask since the more etchant is consumed. The condition with a small amount of etchant is achieved by decreasing the pressure of a chamber where dry etching is performed, or reducing the flow rate of the etching gas. The advantages provided by the structure schematically shown in FIG. 1A or 1B are as described above. Although not shown in FIG. 7, a contact hole, a conductive plug filled therein, and the like are also formed to electrically connect the wiring layer and the lower electrode 130.

Here, the insulating film 120 described with reference to FIGS. 1A to 1C can include a bank-shaped insulator 50 arranged in the region between the adjacent reflective layers 101. The bank-shaped insulator 50 can include the insulating layer 121 arranged in the peripheral portions in the adjacent reflecting layers 101 and the portion between the adjacent reflective layers 101, and the insulating layer 122 covering the insulating layer 121. The insulating film 120 can also include the insulating layer 123 (first insulating layer) covering the reflective layer 101 of each of the plurality of organic EL elements and the insulator 50, and the insulating layer 124 (second insulating layer) covering the insulating layer 123. The insulating layer 123 (first insulating layer) can include a convex portion 51 arranged to cover the insulator 50, and the insulating layer 124 (second insulating layer) can have the trench T on the convex portion 51.

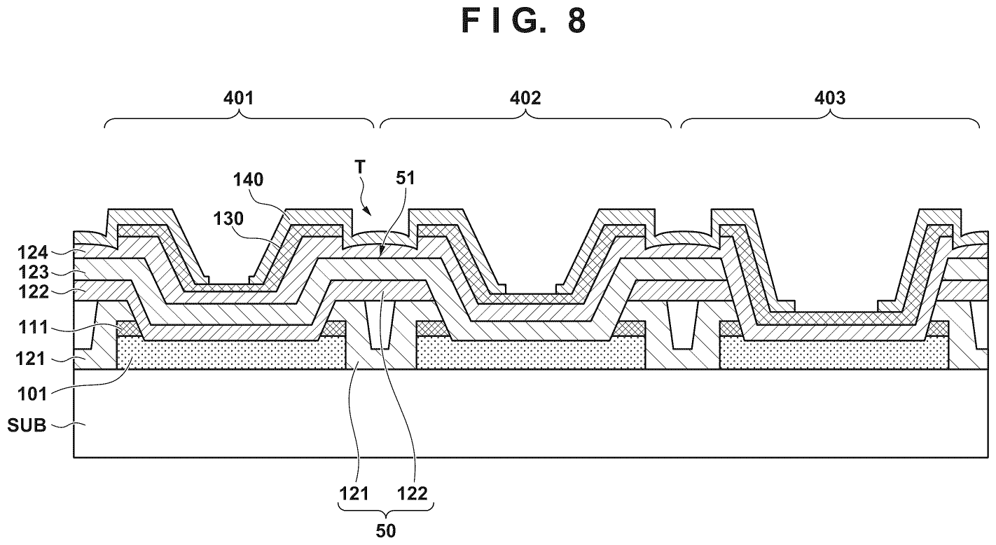

FIG. 8 schematically shows a state after performing step G. In step G, after forming a material film for the insulating layer 140, the material film is patterned to expose the lower electrode 130 of each pixel. This patterning can include a photolithography step and a dry etching step. The insulating layer 140 is formed by, for example, a silicon oxide film, and the material film for the insulating layer 140 is formed by, for example, a plasma CVD method. The insulating layer 140 electrically isolate the lower electrode 130 between the pixels.

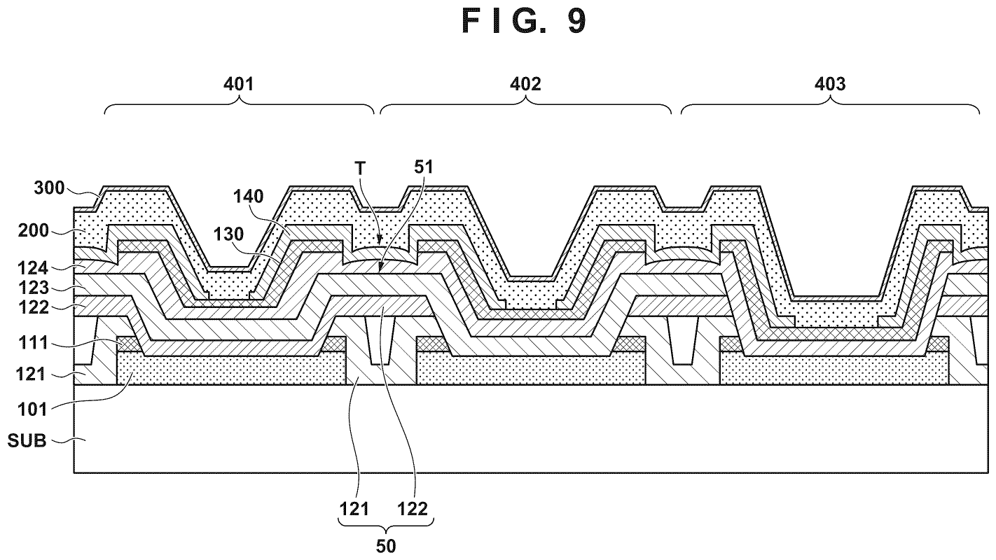

FIG. 9 schematically shows a state after performing step H. In step H, the organic film 200 and the upper electrode 300 are formed. The organic film 200 includes at least a light emitting layer, and may also include a charge injection layer (hole injection layer or electron injection layer), a charge transport layer (hole transport layer or electron transport layer), a charge blocking layer, and the like. The upper electrode 300 is desirably a thin-film transparent material so that the light generated in the organic film 200 is emitted to the upper surface without being blocked. The upper electrode 300 is formed by a thin film of, for example, gold, platinum, silver, aluminum, chromium, magnesium, or an alloy thereof.

In order to allow the light generated in the organic film 200 to be emitted upward, the upper electrode 300 is desirably formed of a thin-film transparent material. For example, the upper electrode 300 is formed by a thin film of, for example, gold, platinum, silver, aluminum, chromium, magnesium, or an alloy thereof.

As has been described above, by performing steps A to H, a microcavity structure having three kinds of thicknesses (T401+Tt, T402+Tt, and T403+Tt) suitable for the light of the wavelength range to be enhanced. With this structure, the light generated in the light emitting layer of the organic film 200 and emitted downward is reflected by the reflective layer 101. Then, the light is resonated/amplified by the optical adjustment layer having a thickness suitable for the wavelength range to be enhanced in the microcavity structure. After step H, a sealing layer, a color filter layer, and the like can be formed on the upper electrode 300, as appropriate.

According to the manufacturing method described above, a leakage current between the pixels can be reduced through the organic film 200.

Application examples in which the light emitting device 1 is applied to an image forming apparatus, a display apparatus, a photoelectric conversion apparatus, electronic equipment, an illumination apparatus, a moving body, and a wearable device will be exemplarily described below.

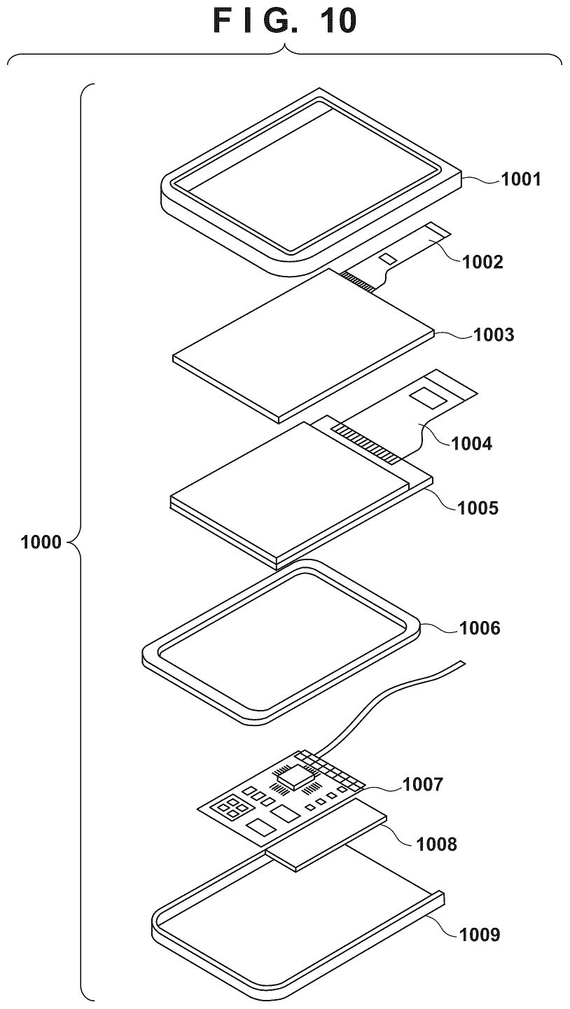

FIG. 10 is a schematic view showing an example of a display apparatus 1000 using the light emitting device 100. The display apparatus 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display apparatus 1000 is not portable equipment. Even when the display apparatus 1000 is portable equipment, the battery 1008 need not be provided at this position. The light emitting device 1 can be applied to the display panel 1005. A plurality of pixels arranged to form the pixel region of the light emitting device 1 functioning as the display panel 1005 operate in a state in which they are connected to the active elements such as transistors arranged on the circuit board 1007.

The display apparatus 1000 shown in FIG. 10 can be used for a display unit of a photoelectric conversion apparatus (also referred to as an image capturing apparatus) including an optical unit having a plurality of lenses, and an image sensor for receiving light having passed through the optical unit and photoelectrically converting the light into an electric signal. The photoelectric conversion apparatus can include a display unit for displaying information acquired by the image sensor. In addition, the display unit can be either a display unit exposed outside the photoelectric conversion apparatus, or a display unit arranged in the finder. The photoelectric conversion apparatus can be a digital camera or a digital video camera.

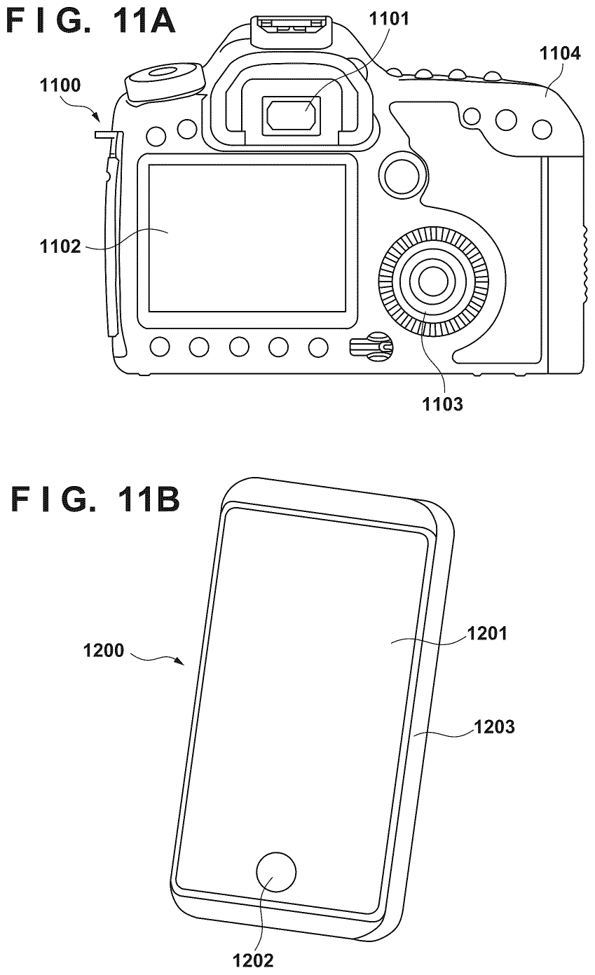

FIG. 11A is a schematic view showing an example of the photoelectric conversion apparatus using the light emitting device 1 according to this embodiment. A photoelectric conversion apparatus 1100 can include a viewfinder 1101, a rear display 1102, an operation unit 1103, and a housing 1104. The photoelectric conversion apparatus 1100 can also be called an image capturing apparatus. The light emitting device 1 according to this embodiment can be applied to the viewfinder 1101 or the rear display 1102 as a display unit. In this case, the pixel region of the light emitting device 1 can display not only an image to be captured but also environment information, image capturing instructions, and the like. Examples of the environment information are the intensity and direction of external light, the moving velocity of an object, and the possibility that an object is covered with an obstacle.

The photoelectric conversion apparatus 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 1 may be applied to a display unit of electronic equipment. At this time, the display unit can have both a display function and an operation function. Examples of the portable terminal are a portable phone such as a smartphone, a tablet, and a head mounted display.

FIG. 11B is a schematic view showing an example of electronic equipment using the light emitting device 1 according to this embodiment. Electronic equipment 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable equipment including the communication unit can also be regarded as communication equipment. The light emitting device 1 according to this embodiment can be applied to the display unit 1201.

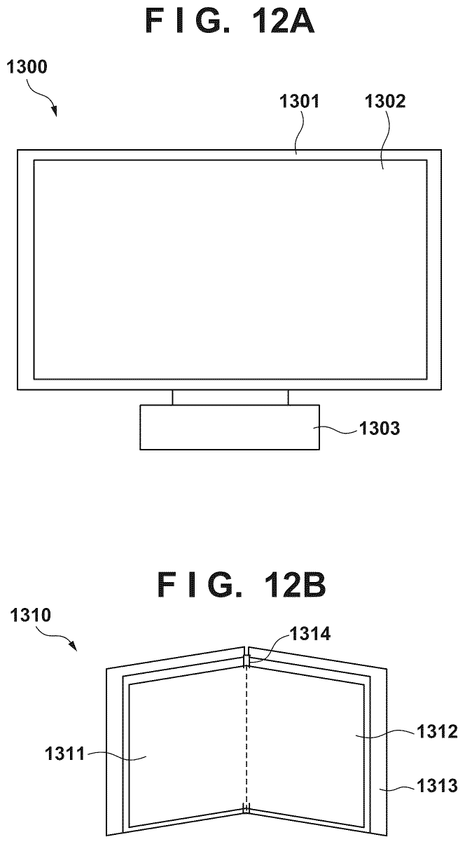

FIGS. 12A and 12B are schematic views showing examples of the display apparatus using the light emitting device 1 according to this embodiment. FIG. 12A shows a display apparatus such as a television monitor or a PC monitor. A display apparatus 1300 includes a frame 1301 and a display unit 1302. The light emitting device 1 according to this embodiment can be applied to the display unit 1302. The display apparatus 1300 can include a base 1303 that supports the frame 1301 and the display unit 1302. The base 1303 is not limited to the form shown in FIG. 12A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 12B is a schematic view showing another example of the display apparatus using the light emitting device 1 according to this embodiment. A display apparatus 1310 shown in FIG. 12B can be folded, and is a so-called foldable display apparatus. The display apparatus 1310 includes a first display unit 1311, a second display unit 1312, a housing 1313, and a bending point 1314. The light emitting device 1 according to this embodiment can be applied to each of the first display unit 1311 and the second display unit 1312. The first display unit 1311 and the second display unit 1312 can also be one seamless display apparatus. The first display unit 1311 and the second display unit 1312 can be divided by the bending point. The first display unit 1311 and the second display unit 1312 can display different images, and can also display one image together.

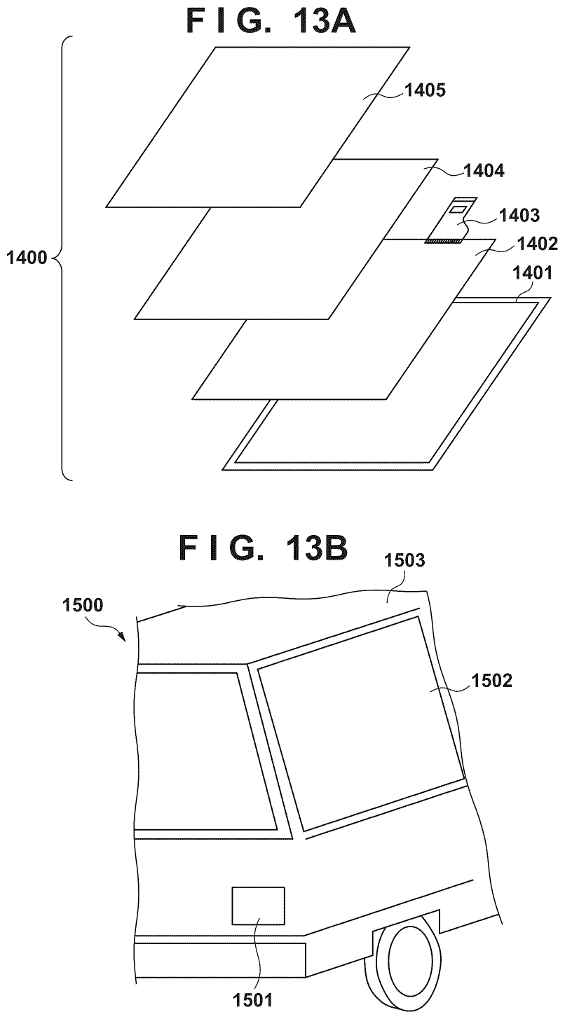

FIG. 13A is a schematic view showing an example of the illumination apparatus using the light emitting device 1 according to this embodiment. An illumination apparatus 1400 can include a housing 1401, a light source 1402, a circuit board 1403, an optical film 1404, and a light diffusing unit 1405. The light emitting device 1 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination apparatus can also include a cover on the outermost portion, as needed. The illumination apparatus 1400 can include both or one of the optical film 1404 and the light diffusing unit 1405.

The illumination apparatus 1400 is, for example, an apparatus for illuminating the interior of the room. The illumination apparatus 1400 can emit white light, natural white light, or light of any color from blue to red. The illumination apparatus 1400 can also include a light control circuit for controlling these light components. The illumination apparatus 1400 can also include a power supply circuit connected to the light emitting device 1 functioning as the light source 1402. The power supply circuit is a circuit for converting an AC voltage into a DC voltage. White has a color temperature of 4,200 K, and natural white has a color temperature of 5,000 K. The illumination apparatus 1400 may also include a color filter. In addition, the illumination apparatus 1400 can include a heat radiation unit. The heat radiation unit radiates the internal heat of the apparatus to the outside of the apparatus, and examples are a metal having a high specific heat and liquid silicon.

FIG. 13B is a schematic view of an automobile having a taillight as an example of a vehicle lighting appliance using the light emitting device 1 according to this embodiment. An automobile 1500 has a taillight 1501, and can have a form in which the taillight 1501 is turned on when performing a braking operation or the like. The light emitting device 1 according to this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 1 according to this embodiment can be applied to the taillight 1501. The taillight 1501 can include a protection member for protecting the light emitting device 1 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 1 according to this embodiment may be used. In this case, the constituent materials of the electrodes and the like of the light emitting device 1 are formed by transparent members.

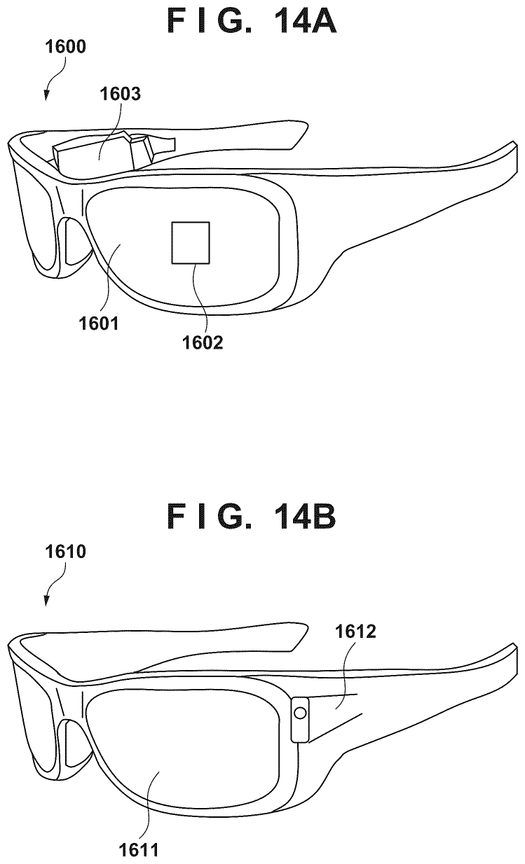

Further application examples of the light emitting device 1 according to this embodiment will be described with reference to FIGS. 14A and 14B. The light emitting device 1 can be applied to a system that can be worn as a wearable device such as smartglasses, a Head Mounted Display (HMD), or a smart contact lens. An image capturing display apparatus used for such application examples includes an image capturing device capable of photoelectrically converting visible light and a light emitting device capable of emitting visible light.

Glasses 1600 (smartglasses) according to one application example will be described with reference to FIG. 14A. An image capturing device 1602 such as a CMOS sensor or an SPAD is provided on the surface side of a lens 1601 of the glasses 1600. In addition, the light emitting device 1 according to this embodiment is provided on the back surface side of the lens 1601.

The glasses 1600 further include a control apparatus 1603. The control apparatus 1603 functions as a power supply that supplies electric power to the image capturing device 1602 and the light emitting device 1 according to each embodiment. In addition, the control apparatus 1603 controls the operations of the image capturing device 1602 and the light emitting device 1. An optical system configured to condense light to the image capturing device 1602 is formed on the lens 1601.

Glasses 1610 (smartglasses) according to one application example will be described with reference to FIG. 14B. The glasses 1610 include a control apparatus 1612, and an image capturing device corresponding to the image capturing device 1602 and the light emitting device 1 are mounted on the control apparatus 1612. The image capturing device in the control apparatus 1612 and an optical system configured to project light emitted from the light emitting device 1 are formed in a lens 1611, and an image is projected to the lens 1611. The control apparatus 1612 functions as a power supply that supplies electric power to the image capturing device and the light emitting device 1, and controls the operations of the image capturing device and the light emitting device 1. The control apparatus 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 1 according to the embodiment of the present disclosure can include an image capturing device including a light receiving element, and control a displayed image based on the line-of-sight information of the user from the image capturing device.

More specifically, the light emitting device 1 decides a first visual field region at which the user is gazing and a second visual field region other than the first visual field region based on the line-of-sight information. The first visual field region and the second visual field region may be decided by the control apparatus of the light emitting device 1, or those decided by an external control apparatus may be received. In the display region of the light emitting device 1, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control apparatus of the light emitting device 1, or those decided by an external control apparatus may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 1, the image capturing device, or an external apparatus. If the external apparatus holds the AI program, it is transmitted to the light emitting device 1 via communication.

When performing display control based on line-of-sight detection, smartglasses further including an image capturing device configured to capture the outside can be applied. The smartglasses can display captured outside information in real time.

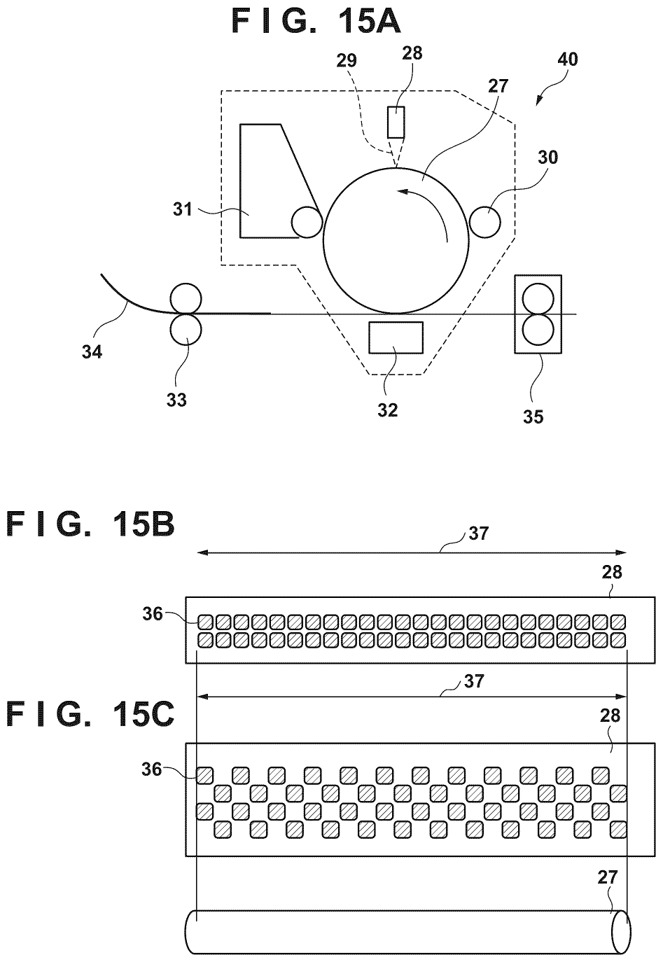

FIGS. 15A to 15C are schematic views showing an example of an image forming apparatus using the light emitting device 1 according to this embodiment. An image forming apparatus 40 shown in FIG. 15A includes a photosensitive member 27, an exposure light source 28, a developing unit 31, a charging unit 30, a transfer device 32, a conveyance unit 33 (a conveyance roller in the arrangement shown in FIG. 15A), and a fixing device 35.

Light 29 is emitted from the exposure light source 28, and an electrostatic latent image is formed on the surface of the photosensitive member 27. The light emitting device 1 can be applied to the exposure light source 28. The developing unit 31 can function as a developing device that includes a toner or the like as a developing agent and applies the developing agent to the exposed photosensitive member 27. The charging unit 30 charges the photosensitive member 27. The transfer device 32 transfers the developed image to a print medium 34. The conveyance unit 33 conveys the print medium 34. The print medium 34 can be, for example, paper, a film, or the like. The fixing device 35 fixes the image formed on the print medium.

Each of FIGS. 15B and 15C is a schematic view showing a form in which a plurality of light emitting units 36 are arranged in the exposure light source 28 along the longitudinal direction of a long substrate. The light emitting device 1 can be applied to each of the light emitting units 36. That is, a plurality of pixels arranged to form a pixel array are arranged along the longitudinal direction of the substrate. A direction 37 is a direction parallel to the axis of the photosensitive member 27. This column direction matches the direction of the axis upon rotating the photosensitive member 27. This direction 37 can also be referred to as the long-axis direction of the photosensitive member 27.

FIG. 15B shows a form in which the light emitting units 36 are arranged along the long-axis direction of the photosensitive member 27. FIG. 15C shows a form, which is a modification of the arrangement of the light emitting units 36 shown in FIG. 15B, in which the light emitting units 36 are arranged in the column direction alternately between the first column and the second column. The light emitting units 36 are arranged at different positions in the row direction between the first column and the second column. In the first column, the plurality of light emitting units 36 are arranged apart from each other. In the second column, the light emitting unit 36 is arranged at the position corresponding to the space between the light emitting units 36 in the first column. Furthermore, in the row direction, the plurality of light emitting units 36 are arranged apart from each other. The arrangement of the light emitting units 36 shown in FIG. 15C can be referred to as, for example, an arrangement in a grid pattern, an arrangement in a staggered pattern, or an arrangement in a checkered pattern.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-207168, filed Dec. 7, 2023, which is hereby incorporated by reference herein in its entirety.

What is claimed is:

1. A light emitting device including a plurality of organic EL elements arranged on a substrate, comprising
an insulating film configured to insulate adjacent lower electrodes from each other among lower electrodes of the plurality of organic EL elements,
wherein
the insulating film has a trench between the adjacent lower electrodes, and
a surface of the trench includes two opposing wall surfaces and a bottom surface located between the two wall surfaces, the bottom surface includes a convex surface protruding in a direction away from the substrate, and in an opposing direction of the two wall surfaces, a width of the convex surface is not less than ⅓ of a shortest distance between the two wall surfaces.

2. The device according to claim 1, wherein
the bottom surface includes a non-convex surface between the two wall surfaces and the convex surface, and in the opposing direction of the two wall surfaces, a width of the non-convex surface is smaller than the width of the convex surface.

3. The device according to claim 1, further comprising an insulating layer covering a peripheral portion in the lower electrode and the trench,
wherein the plurality of organic EL elements include a plurality of organic layers covering the lower electrode and the insulating film.

4. The device according to claim 3, wherein
in at least one organic layer of the plurality of organic layers, a thickness of a portion arranged on a peripheral portion in the bottom surface is smaller than a thickness of a portion arranged on a central portion in the bottom surface.

5. The device according to claim 3, wherein
in at least one organic layer of the plurality of organic layers, a thickness of a portion arranged on a peripheral portion in the bottom surface is smaller than a thickness of a portion arranged on the convex surface.

6. The device according to claim 4, wherein
each of the plurality of organic EL elements includes an upper electrode,
the plurality of organic layers include a light emitting layer, and a charge generation layer arranged between the light emitting layer and the upper electrode, and
the at least one organic layer includes the charge generation layer.

7. The device according to claim 6, wherein
a difference between a thickness of the upper electrode on the peripheral portion and a thickness of the upper electrode on the central portion is smaller than a difference between a thickness of the charge generation layer on the peripheral portion and a thickness of the charge generation layer on the central portion.

8. The device according to claim 2, further comprising an insulating layer covering a peripheral portion in the lower electrode and the trench,
wherein
the plurality of organic EL elements include a plurality of organic layers covering the lower electrode and the insulating film, and
in at least one organic layer of the plurality of organic layers, a thickness of a portion arranged on the non-convex surface of the bottom surface is smaller than a thickness of a portion arranged on the convex surface.

9. The device according to claim 8, wherein
each of the plurality of organic EL elements includes an upper electrode,
the plurality of organic layers include a light emitting layer, and a charge generation layer arranged between the light emitting layer and the upper electrode, and
the at least one organic layer includes the charge generation layer.

10. The device according to claim 9, wherein
a difference between a thickness of the upper electrode on the non-convex surface and a thickness of the upper electrode on the convex surface is smaller than a difference between a thickness of the charge generation layer on the non-convex surface and a thickness of the charge generation layer on the convex surface.

11. The device according to claim 1, wherein
each of the plurality of organic EL elements includes a reflective layer arranged below the lower electrode, and the insulating film is arranged to cover the reflective layer of each of the plurality of organic EL elements and a region between adjacent reflective layers among the reflective layers of the plurality of organic EL elements.

12. The device according to claim 11, wherein
the insulating film includes a bank-shaped insulator arranged in the region between the adjacent reflective layers, a first insulating layer covering the reflective layers of the plurality of organic EL elements and the insulator, and a second insulating layer covering the first insulating layer, and
the first insulating layer includes a convex portion arranged to cover the insulator, and the second insulating layer has the trench on the convex portion.

13. The device according to claim 12, wherein
the plurality of organic EL elements include a first organic EL element where a thickness of the insulating film between the reflective layer and the lower electrode is a first thickness, and a second organic EL element where a thickness of the insulating film between the reflective layer and the lower electrode is a second thickness.

14. An image forming apparatus comprising a photosensitive member, an exposure light source configured to expose the photosensitive member, a developing device configured to apply a developing agent to the exposed photosensitive member, and a transfer device configured to transfer an image developed by the developing device to a print medium,
wherein the exposure light source includes a light emitting device defined in claim 1.

15. A display apparatus comprising a light emitting device defined in claim 1, and an active element connected to the light emitting device.

16. A photoelectric conversion apparatus comprising an optical unit including a plurality of lenses, an image sensor configured to receive light having passed through the optical unit, and a display unit configured to display an image,
wherein the display unit displays an image captured by the image sensor, and includes a light emitting device defined in claim 1.

17. Electronic equipment comprising a housing provided with a display unit, and a communication unit provided in the housing and configured to perform external communication,
wherein the display unit includes a light emitting device defined in claim 1.

18. An illumination apparatus comprising a light source, and at least one of a light diffusing unit and an optical film,
wherein the light source includes a light emitting device defined in claim 1.

19. A moving body comprising a main body, and a lighting appliance provided in the main body,
wherein the lighting appliance includes a light emitting device defined in claim 1.

20. A wearable device comprising a display apparatus configured to display an image,
wherein the display apparatus includes a light emitting device defined in claim 1.
